(19) United States
(12) Patent Application Publication
(10) Pub. No.: US 2026/0078522 A1
(43) Pub. Date: Mar. 19, 2026

(54) GROUP III NITRIDE SINGLE CRYSTAL GROWTH METHOD

(71) Applicants: TOYODA GOSEI CO., LTD., Kiyosu-shi (JP); THE UNIVERSITY OF OSAKA, Osaka (JP)

(72) Inventors: Taku FUJIMORI, Kiyosu-shi (JP); Miki MORIYAMA, Kiyosu-shi (JP); Yusuke MORI, Osaka (JP); Masayuki IMANISHI, Osaka (JP); Shigeyoshi USAMI, Osaka (JP)

(21) Appl. No.: 19/317,770

(22) Filed: Sep. 3, 2025

(30) Foreign Application Priority Data
Sep. 17, 2024 (JP) 2024-159684

(51) Int. Cl. C30B 19/02; C30B 19/12; C30B 29/40

(52) U.S. Cl. CPC C30B 19/02; C30B 19/12; C30B 29/406

(57) ABSTRACT

A Group III nitride single crystal growth method is a method for growing a Group III nitride single crystal on a Group III nitride substrate, and includes: repeatedly performing, to form a thickened Group III nitride single crystal on the Group III nitride substrate, a process of: immersing the Group III nitride substrate in a mixed melt containing a Group III metal and Na stored in a crucible; pulling up the Group III nitride substrate from the mixed melt; and heating the Group III nitride substrate, pulled up from the mixed melt, in a nitrogen atmosphere, and the crucible is an alumina crucible containing alumina as a main component and containing an alkali metal other than Na or an alkaline earth metal.

### CROSS-REFERENCE TO RELATED APPLICATION

This application is based on and claims priority under 35 USC 119 from Japanese Patent Application No. 2024-159684 filed on Sep. 17, 2024.

### TECHNICAL FIELD

The present invention relates to a Group III nitride single crystal growth method.

### BACKGROUND ART

In the conventional art, there is known a flux method in which a GaN single crystal is grown on a GaN substrate to form a thickened GaN single crystal by immersing the GaN substrate in a Ga—Na melt, which is a Ga—Na mixed melt. In this method, as a result of three-dimensional growth of the GaN single crystal, crystal growth that forms large steps (macrosteps) on the order of several μm to several hundred μm, known as macrostep growth, is observed. In a macrostep growth region, a mass of Ga—Na melt called an inclusion is formed in the crystal, and thus a crystal quality decreases.

In order to prevent the formation of such an inclusion, Patent Literature 1 discloses a method in which an alkaline earth metal such as Ca is added to a Ga—Na melt in advance to improve wettability of the Ga—Na melt with respect to a GaN substrate, and the GaN substrate is immersed in the Ga—Na melt and then heated in a nitrogen atmosphere, and the operations are repeated to form a thickened GaN single crystal on the GaN substrate. Accordingly, since the macrostep growth is prevented, the formation of the inclusion is prevented, and the crystal quality is improved.

Patent Literature 1: JP2019-19040A

### SUMMARY OF INVENTION

However, in the configuration disclosed in Patent Literature 1, since the alkaline earth metal added to the Ga—Na melt in advance is 0.05 mol % or more, a large amount of miscellaneous crystals other than the GaN single crystal are formed during the crystal growth. Therefore, there is room for improvement in improving the crystal quality of the GaN single crystal.

The present invention has been made in view of the above problems, and aims to provide a GaN single crystal growth method capable of improving a crystal quality.

One aspect of the present invention provides a Group III nitride single crystal growth method, which is a method for growing a Group III nitride single crystal on a Group III nitride substrate, the method including:
a thickening step of repeatedly performing a process of immersing the Group III nitride substrate in a mixed melt containing a Group III metal and Na stored in a crucible, pulling up the Group III nitride substrate from the mixed melt, and then heating the Group III nitride substrate in a nitrogen atmosphere, to form a thickened Group III nitride single crystal on the Group III nitride substrate, in which
the crucible is an alumina crucible containing alumina as a main component and containing an alkali metal other than Na or an alkaline earth metal.

In the Group III nitride single crystal growth method according to the above aspect, since the mixed melt containing a Group III metal and Na is stored in the alumina crucible containing an alkali metal other than Na or an alkaline earth metal, an extremely small amount of the alkali metal other than Na or the alkaline earth metal is melted into the mixed melt. Accordingly, wettability of the mixed melt with respect to the Group III nitride substrate can be improved, and formation of an inclusion is prevented. Further, since the amount of the alkali metal other than Na or the alkaline earth metal contained in the mixed melt is extremely small, formation of a miscellaneous crystal is also prevented. As a result, both the prevention of the formation of the inclusion and the prevention of the formation of the miscellaneous crystal are achieved, so that a crystal quality of the Group III nitride single crystal can be improved.

As described above, according to the above aspect, it is possible to provide a Group III nitride single crystal growth method capable of improving the crystal quality.

### BRIEF DESCRIPTION OF DRAWINGS

FIG. 1 is a flowchart showing a GaN single crystal growth method according to a first embodiment.

FIG. 2 is a drawing including (a) a conceptual diagram of a seed substrate on which a plurality of seed crystals are formed, (b) a conceptual diagram of a seed substrate on which a plurality of initial nuclei are formed, (c) a conceptual diagram showing a state where a GaN single crystal is formed between the plurality of initial nuclei, and (d) a conceptual diagram showing a state where a GaN single crystal is grown on a flattened crystal surface, according to the first embodiment.

FIG. 3 is a plan view showing a configuration of a seed substrate according to the first embodiment.

FIG. 4 is a cross-sectional view showing a configuration of a seed crystal according to the first embodiment, which is a cross-sectional view perpendicular to a substrate main surface.

FIG. 5 is a plan view showing a configuration of the seed crystal according to the first embodiment.

FIG. 6 is a drawing including (a) a first conceptual diagram and (b) a second conceptual diagram illustrating an initial nucleus forming step according to the first embodiment.

FIG. 7 is a conceptual diagram illustrating a flattening step according to the first embodiment.

FIG. 8 is a conceptual diagram illustrating a thickening step according to the first embodiment.

FIG. 9 is a cross-sectional view perpendicular to the substrate main surface after the thickening step according to the first embodiment.

### DESCRIPTION OF EMBODIMENTS

The alkali metal other than Na or the alkaline earth metal melted from the crucible in the thickening step is preferably mixed in the mixed melt at a ratio of 0.01 mol % to less than 0.05 mol %. In this case, since the ratio of the alkali metal other than Na or the alkaline earth metal contained in the mixed melt in the thickening step is extremely small, both the prevention of the formation of the inclusion and the prevention of the formation of the miscellaneous crystal can be further achieved.

In the thickening step, an immersion time, which is a time for immersing the Group III nitride substrate in the mixed melt, is preferably within a range of 1 minute to 10 minutes, and a vapor phase heating time, which is a time for heating the Group III nitride substrate in the nitrogen atmosphere after being pulled up from the mixed melt, is preferably within a range of 10 minutes to 120 minutes. The immersion time is relatively short, but is sufficient for supplying the mixed melt to the upper surface of the Group III nitride substrate, and the vapor phase heating time is sufficient for growing a Group III nitride single crystal using, as a raw material, the mixed melt supplied to the upper surface of the Group III nitride substrate. Therefore, in the thickening step, the growth of the Group III nitride single crystal can be efficiently performed while preventing formation of a macrostep.

The Group III nitride single crystal growth method can further include: an initial nucleus forming step of immersing, in the mixed melt stored in the crucible, a seed substrate having a plurality of seed crystals, made of the Group III nitride single crystal, formed on an upper surface thereof, to grow the Group III nitride single crystal from the plurality of seed crystals and to form the plurality of initial nuclei; and a flattening step of repeatedly performing a process of: immersing the seed substrate having the initial nuclei formed thereon in the mixed melt stored in the crucible; pulling up the seed substrate from the mixed melt; and then heating the seed substrate in a nitrogen atmosphere, to grow the Group III nitride single crystal from the initial nuclei, to fill a space between the adjacent initial nuclei with the Group III nitride single crystal, and to flatten a crystal surface, in which in the thickening step, the seed substrate having the flattened crystal surface formed in the flattening step is used as the Group III nitride substrate. In this case, a thickened Group III nitride single crystal having a high crystal quality can be formed on the seed substrate.

A ratio of the alkali metal other than Na or the alkaline earth metal in the mixed melt preferably increases in an order of the initial nucleus forming step, the flattening step, and the thickening step. In this case, even when the wettability of the mixed melt with respect to the seed substrate is improved in the initial nucleus forming step, an influence on crystal formation is small, so that the formation of the miscellaneous crystal in the initial nucleus forming step can be prevented by lowering the ratio of the alkali metal other than Na or the alkaline earth metal in the mixed melt. Further, by improving the wettability of the mixed melt with respect to the seed substrate in the flattening step, the mixed melt is likely to be held on the seed substrate when the seed substrate is pulled up from the mixed melt, so that the flattening of the crystal surface can be promoted. Further, in the thickening step, by further improving the wettability of the mixed melt, both the prevention of the formation of the inclusion and the prevention of the formation of the miscellaneous crystal can be further achieved.

### First Embodiment

### 1. Overview of Flux Method

A Group III nitride single crystal growth method according to a first embodiment is a method for growing a Group III nitride single crystal by using a flux method. Accordingly, a Group III nitride semiconductor is produced. The flux method is a method for epitaxially growing a Group III nitride semiconductor in a liquid phase by supplying and melting a nitrogen-containing gas to a mixed melt containing an alkali metal to be a flux and a Group III metal as a raw material.

In the present embodiment, the mixed melt contains Na as an alkali metal to be a flux. The Group III metal as a raw material is at least one of gallium (Ga), aluminum (Al), and indium (In), and a composition of a Group III nitride single crystal to be formed can be controlled based on a ratio thereof. GaN, AlN, InN, AlGaN, InGaN, AlGaInN, and the like can be formed. The present invention is particularly suitable for formation of GaN, and the first embodiment is a method for growing a GaN single crystal. In addition, Na is used as the flux, and such a flux method is particularly referred to as a Na flux method. The nitrogen-containing gas is a gas of a compound containing nitrogen molecules or nitrogen such as ammonia as constituent elements, and may be a mixed gas thereof, or the nitrogen-containing gas may be mixed with an inert gas such as a rare gas.

### 2. Configuration of Crucible

In the first embodiment, an alumina crucible containing alumina as a main component and containing an alkali metal other than Na or an alkaline earth metal is used as a crucible, which is a vessel for storing a mixed melt for growing a GaN single crystal. Hereinafter, a crucible that can be used in the present embodiment will be exemplified. Note that, the crucible to be used in the present embodiment is not limited to the following configuration.

The crucible that can be used in the present embodiment is a ceramic (a sintered body of aluminum oxide) containing alumina as a main component, and has high heat resistance and alkali resistance. The crucible may be provided with a lid. An abnormally grown alumina grain is observed on an inner wall surface of the crucible, and a maximum grain diameter of the abnormally grown alumina grain is 10 μm or more. The grain diameter is defined as the diameter of a circumscribed circle of the grain. A number density of the abnormally grown alumina grains on the inner wall surface is approximately 10 to 10,000 grains/1 mm square (the number of the alumina grains that have undergone the abnormal grain growth per 1 mm square).

Here, the abnormal grain growth is growth in which alumina grains having a grain diameter (for example, a grain diameter on the order of one digit or more) larger than the grain diameter of normal alumina grains, in which the abnormal grain growth does not occur, are generated. When the grain diameter of the alumina grains before sintering is uniform, the grain diameter of the alumina grains should be uniform even after sintering, but when the abnormal grain growth occurs, alumina grains having a grain diameter larger than that of normal alumina grains are generated. In the case where the abnormal grain growth does not occur, the grain diameter of the alumina grains is approximately uniform and circular, and a grain diameter distribution is a mountain-shaped distribution having one peak.

On the other hand, in the case where the abnormal grain growth occurs, the alumina grains having a grain diameter larger than the grain diameter in the case where the abnormal grain growth does not occur are generated, and there are not only alumina grains having a circular shape but also alumina grains having a shape close to an elliptical shape. In addition, the grain diameter distribution has a peak of the grain diameter of the alumina grains that do not undergo the abnormal grain growth and a peak of the grain diameter of the alumina grains that have undergone the abnormal grain growth at a position where the grain diameter is larger than the peak. In addition, the grain diameters of the alumina grains that have undergone the abnormal grain growth are approximately aligned with each other.

The crucible is prepared by casting using a gypsum mold. Specifically, it is prepared as follows. First, an alumina powder as a raw material and water are mixed to prepare a slurry (suspension), which is poured into a gypsum mold made of gypsum. A wet jet mill treatment or the like is used to prepare the slurry. Then, the gypsum mold is allowed to stand for a predetermined time to absorb moisture, and the alumina powder having a constant thickness is deposited on a surface of the gypsum mold. Next, the liquid slurry remaining in the gypsum mold is discarded, and only the alumina powder layer deposited on the surface of the gypsum mold is allowed to be remain. The remaining alumina powder layer is dried for a predetermined time, and the deposited alumina powder layer is solidified to obtain a molded body. Then, the molded body is taken out of the gypsum mold, and the molded body is sintered in air at 1570° C. to produce a crucible, which is a sintered body of alumina.

In this production method, impurities such as Ca, C, and O are melted from the gypsum mold into the slurry, and the molded body contains these impurities. Accordingly, the crucible according to the first embodiment contains at least Ca, which is an alkaline earth metal. This impurity is thought to be a factor that causes the abnormal grain growth during the sintering. Note that, the impurity is a component having a sufficiently small content ratio with respect to a main component, and the main component refers to a component having the largest content ratio.

Therefore, when a crucible is formed by casting using a gypsum mold, there may be alumina grains that have undergone the abnormal grain growth. Therefore, as the crucible to be used in the first embodiment, a plurality of crucibles are prepared by casting using a gypsum mold, and a crucible satisfying the following conditions is selected and used. The conditions are that the alumina grains that have undergone the abnormal grain growth are present on the inner wall surface of the crucible and that the maximum grain diameter of the alumina grains that have undergone the abnormal grain growth is 10 μm or more.

Note that, the grain diameter of the alumina grains can be easily measured by observation using a microscope. In particular, it is desirable to measure the maximum grain diameter by observing a bottom surface of the inner wall surface of the crucible. This is because the melt is always in contact with the bottom surface of the crucible. In addition, in selecting the crucible, it is not necessary to measure the grain diameter of the alumina grains that have undergone the abnormal grain growth on the entire inner wall surface of the crucible, and it is sufficient to measure the grain diameter of the alumina grains that have undergone the abnormal grain growth, which are present within a predetermined range randomly selected. For example, it is sufficient to randomly select a range of 100 μm square or 1 mm square, to search for the alumina grains that have undergone the abnormal grain growth within this range, and to measure the grain diameter, and it is sufficient to select a crucible having a maximum grain diameter of 10 μm or more.

When GaN is to be grown by the Na flux method using such a crucible, macrostep growth can be prevented as to be described later, and the crystal quality of GaN can be improved. In order to further improve the effect of preventing the macrostep growth, alumina grains having a maximum grain diameter of 10 μm to 150 μm is desirably used. The maximum grain diameter is more desirably 40 μm to 100 μm.

In addition, it is desirable to use a crucible in which the number density of the alumina grains that have undergone the abnormal grain growth on the inner wall surface (particularly, the bottom surface) of the crucible is 10 to 10,000 grains/1 mm square. This is because the macrostep growth is further prevented and a GaN crystal having good crystallinity is obtained. The number being more than 10,000 per 1 mm square is not desirable since a strength of the crucible decreases. It is more desirably 50 to 2,000 grains/1 mm square, and still more desirably 100 to 1,000 grains/1 mm square.

Note that, in the above method, the alumina grains naturally undergo the abnormal grain growth due to mixing of impurities such as Ca from the gypsum mold, but an alkali metal other than Na or an alkaline earth metal may be added to the slurry to artificially cause the abnormal grain growth. Li can be adopted as the alkali metal other than Na, and Ba, Mg, or Sr can be adopted as the alkaline earth metal other than Ca.

Various conditions in the casting may be as follows. An average particle diameter of the alumina powder used for preparing the slurry is preferably 0.1 μm to 1 μm. The alumina grains in the crucible is denser, and the strength can be improved.

Although water is used as a solvent for the slurry, any solvent known used as a solvent for a slurry, such as alcohol, ketone, or amine, may be used. However, it is preferable to use water from the viewpoint of absorption of the solvent into the mold, an environmental load, and absence of the solvent remaining in the crucible. The water is preferably distilled water from the viewpoint of preventing contamination with impurities.

In addition, although the gypsum mold is used as the mold, a mold made of any material can be used as long as the mold can absorb the solvent for the slurry and mix impurities into the slurry. Alternatively, in the case of using a mold made of a material in which impurities are not much melted in the slurry, the impurities may be added to the slurry to artificially cause the abnormal grain growth. However, it is desirable to use a gypsum mold as the mold for casting. This is because it is inexpensive and it is easy to mix impurities into the slurry.

A sintering temperature for the molded body is desirably 1500° C. to 1600° C. This is to make the alumina grains dense and prevent the alumina grains from being too large.

In addition, a sintering aid for promoting the sintering, a dispersant for uniformly dispersing the alumina powder in the solvent, and the like may be added to the slurry. In the case of adding a dispersant, a heat treatment for removing the dispersant from the molded body may be performed at a temperature lower than the temperature at which the molded body is sintered, before sintering the molded body.

In addition, the crucible may be formed by a method other than the casting as long as the alumina grains in the crucible can undergo the abnormal grain growth.

### 3. Details of Group III Nitride Single Crystal Growth Method

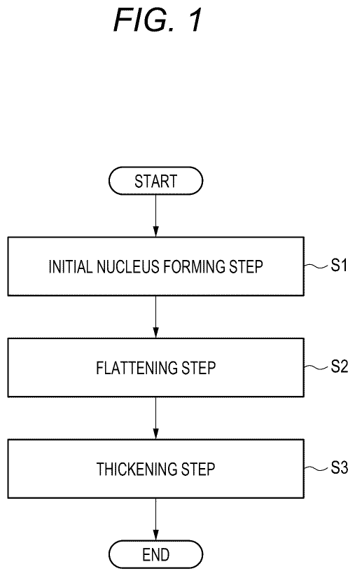

As shown in FIG. 1, a Group III nitride single crystal growth method according to the first embodiment includes an initial nucleus forming step S1, a flattening step S2, and a thickening step S3. Hereinafter, each step will be described in detail. Note that, in the first embodiment, a method for growing a GaN single crystal, which is a Group III nitride single crystal, will be described.

### 3-1. Initial Nucleus Forming Step S1

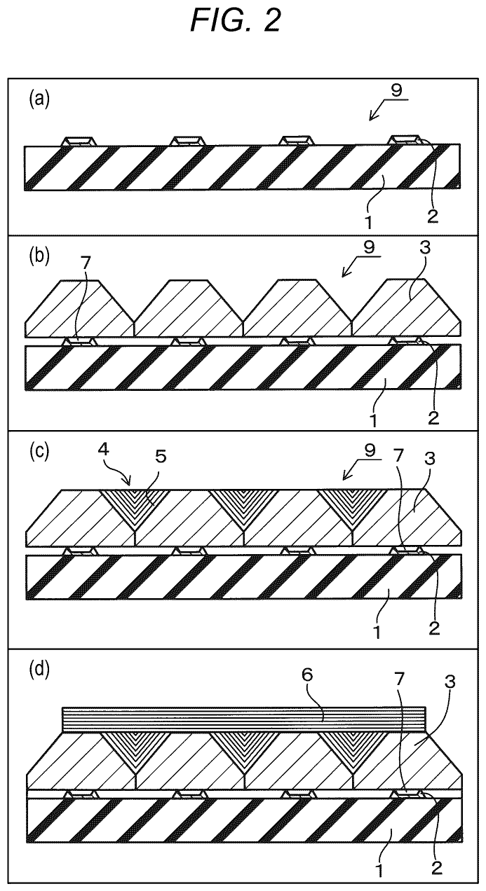

The initial nucleus forming step S1 is a step of immersing, in the mixed melt stored in the crucible, a seed substrate 9 (see (a) of FIG. 2) made of the GaN single crystal and having a plurality of seed crystals 2 formed on an upper surface thereof, to grow a GaN single crystal from the plurality of seed crystals 2 and to form a plurality of initial nuclei 3. It is preferable that the seed substrate 9 is heated and pressurized to reach a growth temperature and a growth pressure, and then charged into the mixed melt. Melt back of the seed crystal 2 in the seed substrate 9 can be prevented.

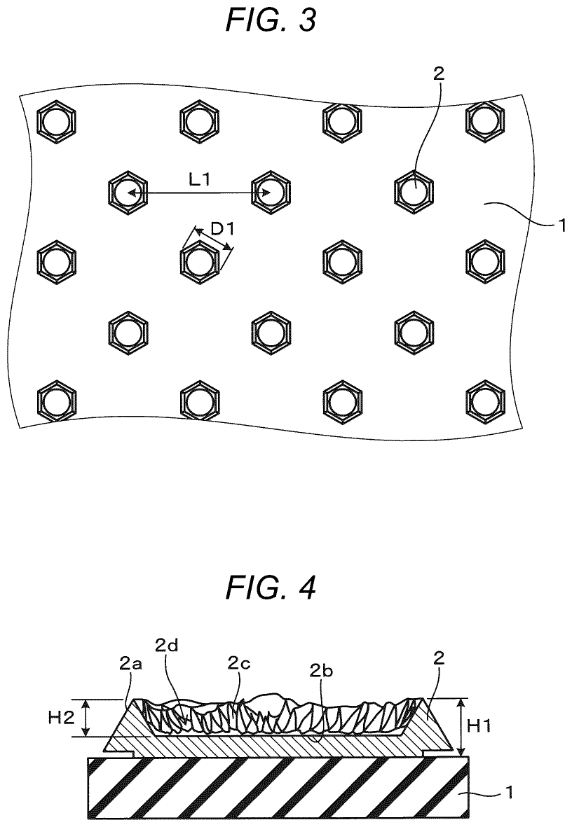

A multi-point seed (MPS) substrate is used as the seed substrate 9. The MPS substrate is a substrate in which a plurality of dot-shaped seed crystals 2 are periodically arranged on a substrate 1. (a) to (d) of FIG. 2 are each a cross-sectional view of the seed substrate 9, the cross section being perpendicular to a substrate main surface. FIG. 3 is a plan view of the seed substrate 9 as viewed from above.

As the substrate 1, a Group III nitride semiconductor, sapphire, aluminum oxynitride, SiC, Si, spinel, ZnO, gallium oxide, or the like can be used. In the case of a sapphire substrate, it is, for example, a substrate having a c plane or a plane as a main surface.

The plurality of seed crystals 2 are provided on the substrate 1 via a buffer layer (not shown). The seed crystals 2 are arranged in a regular triangular lattice pattern. The buffer layer and the seed crystal 2 are each a Group III nitride semiconductor having any composition such as GaN, AlGaN, and AlN. A material of the buffer layer is appropriately selected depending on a material of the seed crystal 2. For example, in the case where the seed crystal 2 is GaN, the buffer layer is preferably GaN. The material of the seed crystal 2 is usually a Group III nitride semiconductor having a composition same as that of the Group III nitride semiconductor to be grown by the flux method. The seed crystal 2 may be grown by any method such as a MOCVD method, a HVPE method, or a MBE method, and the MOCVD method or the HVPE method is preferred in terms of crystallinity, a growth time, and the like.

The seed crystals 2 are arranged in a regular triangular lattice pattern as shown in FIG. 3. It is not limited to a regular triangular lattice shape and is any as long as it is a periodic array. A pattern having high symmetry such as a square lattice shape or a regular triangular lattice shape is preferred. Group III nitride semiconductors grown from respective seed crystals 2 can be uniformly combined, and a Group III nitride semiconductor having less dislocation and warpage can be grown. In the case of a regular triangular lattice pattern, an arrangement direction thereof preferably coincides with an a-axis direction or an m-axis direction of the seed crystal 2. Coincidence here does not mean complete coincidence, and a deviation of an angle of about 10 degrees is allowed as an error. The deviation of the angle is preferably 1 degree or less.

A distance L1 between centers of the adjacent seed crystals 2 is preferably 100 μm to 2000 μm. Within this range, a Group III nitride semiconductor having less dislocation and warpage can be grown. The distance L1 is more preferably 200 μm to 1500 μm, and still more preferably 300 μm to 1000 μm.

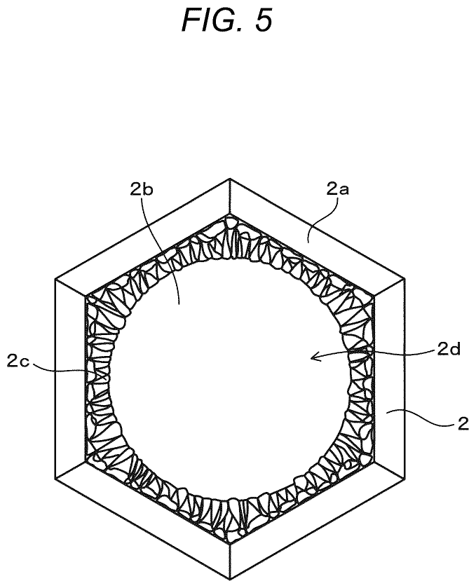

Next, the shape of the seed crystal 2 will be described in detail. FIG. 4 is a cross-sectional view showing a configuration of the seed crystal 2, which is a cross-sectional view perpendicular to the substrate main surface. FIG. 5 is a plan view showing the configuration of the seed crystal 2. As shown in FIGS. 4 and 5, the seed crystal 2 has a disk portion having a disk shape and a regular hexagonal truncated pyramid portion having a regular hexagonal truncated pyramid shape located on and in contact with the disk portion, and has a shape in which a recess 2d is provided at a center of the regular hexagonal truncated pyramid portion.

As to be described later, the seed crystal 2 is formed by selective growth using a mask, and the crystal is laterally grown from an opening of the mask. The mask has a circular opening pattern. Therefore, the mask opening portion remains in a disk shape after the mask is removed. The remaining portion is the disk portion. A shape of the disk portion is equal to a shape of the mask opening when the seed crystal 2 is selectively grown. A diameter D1 of the regular hexagonal truncated pyramid portion is larger than a diameter of the disk portion. Since the disk portion is circular in a plan view, when the substrate 1 is separated after the GaN single crystal is grown by the flux method, a stress can be dispersed, and generation of cracks in the grown crystal can be prevented. Note that, depending on the opening pattern of the mask, a shape such as a regular hexagonal plate or the like may be used instead of the disk portion, but a disk is preferred from the viewpoint of dispersing a stress as described above.

A bottom surface of the regular hexagonal truncated pyramid portion of the seed crystal 2 is a regular hexagon. In particular, a regular hexagon in which each side is aligned with an m plane of the seed crystal 2 (each side coincides with the a-axis direction) is preferred. Since the Group III nitride semiconductor is hexagonal, Group III nitride semiconductors grown from regular hexagonal truncated pyramid portions of respective seed crystals 2 can be uniformly combined by forming a regular hexagon. However, it is not necessary to completely coincide with the a-axis, and a deviation of an angle of about 10 degrees is allowed. The deviation of the angle is preferably 1 degree or less.

Six side surfaces 2a of the regular hexagonal truncated pyramid portion of the seed crystal 2 are a (10-11) plane of the Group III nitride semiconductor. The (10-11) plane is a stable plane in the mixed melt in the Na flux method. Therefore, the initial nucleus 3 to be described later grows from the side surface 2a of the regular hexagonal truncated pyramid portion of the seed crystal 2 while maintaining the (10-11) plane. As a result, a shape of the initial nucleus 3 can be made uniform. Note that, the entire side surface 2a does not need to be the (10-11) plane, but it is preferable that 95% or more of the entire side surface 2a is the (10-11) plane. The (10-11) plane referred to here also includes a plane forming an angle of −5 degrees to 5 degrees with respect to the (10-11) plane as an error.

The diameter D1 (diameter of a circumscribed circle in a plan view) of the regular hexagonal truncated pyramid portion of the seed crystal 2 is preferably 10 μm to 500 μm. Within this range, a Group III nitride semiconductor having less dislocation and warpage can be grown. In addition, an area of the side surface 2a of the regular hexagonal truncated pyramid portion of the seed crystal 2 can be increased, and the growth of the initial nucleus 3 from the side surface 2a can be facilitated. The diameter D1 is more preferably 50 μm to 300 μm, and still more preferably 100 μm to 200 μm.

A height H1 of the seed crystal 2 is preferably 30 μm or more. Within this range, the area of the side surface 2a can be sufficiently increased, and the crystal can be uniformly grown from each side surface 2a. As a result, the shapes of the initial nuclei 3 grown from the respective seed crystals 2 can be made uniform. However, when the height H1 is too high, there is a problem that it takes time to form the seed crystal 2, and thus, it is preferable to set the height H1 to 100 μm or less. The height H1 is more preferably 20 μm to 60 μm, and still more preferably 30 μm to 50 μm.

For the same reason as above, the height H1 of the seed crystal 2 is preferably 0.01 to 0.6 times the diameter D1 of the seed crystal 2. It is more preferably 0.1 to 0.35 times, and still more preferably 0.15 to 0.3 times.

The recess 2d is provided at the center of the seed crystal 2. By providing the recess 2d, the initial nucleus 3 grown from the seed crystal 2 does not fill the recess 2d, and a void 7 is formed. By forming the void 7, the dislocation of the seed crystal 2 can be prevented from propagating to an upper portion, and a high quality GaN single crystal can be grown.

A bottom surface 2b of the recess 2d is flat and is a (0001) plane (c plane) of the Group III nitride semiconductor. The bottom surface 2b is approximately circular in a plan view. Note that, the bottom surface 2b does not need to be flat and may have irregularities. In addition, the shape of the bottom surface 2b in a plan view does not need to be circular.

A side surface 2c of the recess 2d is formed with a large number of irregularities, and has an inclination of approximately the same as that of the (10-11) plane as a whole. When the side surface 2c has such an irregular shape, the side surface 2c serves as a starting point of crystal growth of the Group III nitride semiconductor, and the upper portion of the seed crystal 2 can be likely to be filled with the Group III nitride semiconductor. Note that, the side surface 2c may be a flat surface.

A depth H2 of the recess 2d is preferably 10 μm to 100 μm. Within such a range, the void 7 is more likely to be formed, and a higher quality Group III nitride semiconductor can be grown. The depth H2 is more preferably 20 μm to 60 μm, and still more preferably 30 μm to 50 μm. For the same reason, the depth H2 of the recess 2d is preferably 0.3 to 1.0 times, and more preferably 0.6 to 0.8 times the height H1 of the seed crystal 2.

A diameter of an upper surface of the recess 2d is in a range in which an upper surface of the seed crystal 2 is not present, and the side surface 2c of the recess 2d and the side surface 2a of the seed crystal 2 are connected to each other at an angle. Therefore, the c plane is not present in the upper portion of the seed crystal 2. There is a possibility that the c plane is melted back in the mixed melt in the Na flux method, which causes a variation in shape of respective initial nuclei 3. In addition, there is a possibility that the dislocation of the seed crystal 2 is propagated to the upper portion by the crystal growth from the c plane. Therefore, when a shape in which the c plane is not present in the upper portion is adopted, it is possible to prevent the variation in shape of the respective initial nuclei 3, and to prevent the propagation of the dislocation of the seed crystal 2 to the upper portion.

In the initial nucleus forming step S1, the seed substrate 9 can be prepared, for example, as follows. First, a mask having a plurality of openings is formed on the substrate 1. The plurality of openings are arranged in a regular triangular lattice pattern. The opening has a circular shape. The shape may be a shape other than a circular shape, such as a regular hexagon, but is preferably a circular shape as in the embodiment in order to form a disk portion and prevent cracks during substrate peeling. A material of the mask may be any material as long as it can prevent the growth of the Group III nitride semiconductor on the mask, and is, for example, SiO₂.

Next, the buffer layer (not shown) and the seed crystal 2 are sequentially selectively grown on the substrate 1 exposed to the opening by a method such as a MOCVD method or a HVPE method. Next, the mask is removed by melt back using hydrofluoric acid or the like. With the above, the seed substrate 9 can be prepared.

Here, when the seed crystal 2 is selectively grown from the opening of the mask, the Group III nitride semiconductor can be facet-grown by appropriately controlling growth conditions, and the shape of the seed crystal 2 can be the shape shown in FIGS. 4 and 5. For example, it is sufficient that the growth temperature is 1120° C. to 1145° C., and a V/III ratio is 970 to 1020. In addition, since the shape is determined by selective growth, the shapes of the respective seed crystals 2 can be made uniform.

In the initial nucleus forming step S1, the initial nuclei 3 can be formed as follows. First, an atmosphere in a furnace is substituted with an inert gas, the inside of the furnace is heated, and then evacuated to sufficiently reduce outgas components such as oxygen in the furnace.

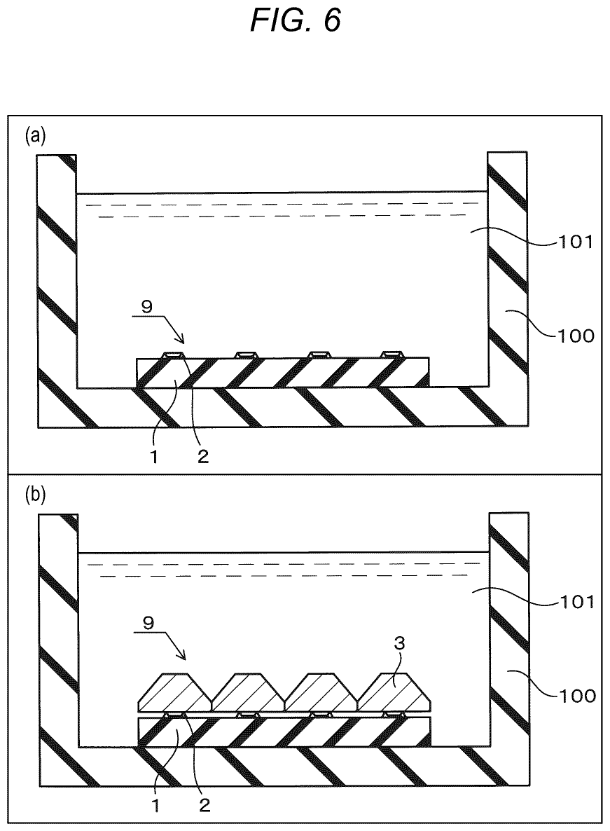

Next, predetermined amounts of Na and Ga are measured in a glove box in which an atmosphere such as oxygen or a dew point is controlled. Thereafter, predetermined amounts of measured Na and Ga are charged into an empty crucible 100 (see FIG. 6). An additive element such as carbon may be added as necessary.

Next, the crucible 100 into which the raw materials are charged and the seed substrate 9 are placed in a reaction vessel, which is then evacuated, and then a nitrogen-containing gas is supplied to the reaction vessel. When a pressure in the reaction vessel reaches the crystal growth pressure, a temperature of the furnace is increased to the crystal growth temperature. The crystal growth temperature is, for example, 700° C. or higher and 1000° C. or lower, and the crystal growth pressure is, for example, 2 MPa or more and 10 MPa or less. In the course of the temperature increase, solid Na and Ga in the crucible 100 are melted into a liquid to form a mixed melt 101. At this stage, the seed substrate 9 is not yet charged into the mixed melt 101.

When the inside of the reaction vessel reaches the crystal growth temperature and the crystal growth pressure and the nitrogen melted in the mixed melt 101 is supersaturated, the seed substrate 9 is charged into the mixed melt 101 in the crucible 100. Then, GaN crystals (initial nuclei 3) grow from the respective seed crystals 2 in the seed substrate 9. The growth of the initial nuclei 3 is performed until the adjacent initial nuclei 3 start to combine with each other (see (b) of FIG. 6). Note that, a gap remains between the initial nucleus 3 and the substrate 1.

Here, the side surface 2a of the regular hexagonal truncated pyramid portion of the seed crystal 2 that is, the (10-11) plane, is stably present in the mixed melt 101 without being melted back. The seed crystal 2 has a height H1 of 30 μm or more, and the side surface 2a has a sufficiently large area. Therefore, the initial nucleus 3 grows from the side surface 2a while maintaining the (10-11) plane. Since the respective seed crystals 2 have a uniform shape and uniformly grow from the seed crystal 2 while maintaining the (10-11) plane, it is possible to prevent the variation in shape of the respective initial nuclei 3 and to make the shapes of the respective initial nuclei 3 uniform.

In addition, since the recess 2d is formed at the center of the seed crystal 2, the initial nucleus 3 does not completely fill the recess 2d, and the void 7 is formed. The mixed melt 101 is confined in the void 7. Since the void 7 is formed in the upper portion of the seed crystal 2, it is possible to prevent the dislocation of the seed crystal 2 from being transferred to the upper portion.

In addition, by increasing the diameter of the recess 2d, the seed crystal 2 has a shape in which the upper surface (c plane) is not present. The c plane may be melted back in the mixed melt 101 and is unstable. Since there is no crystal growth from such an unstable surface, the variation in shape of respective initial nuclei 3 can be further prevented. In addition, since there is no crystal growth from the c plane, it is possible to further prevent the dislocation of the seed crystal 2 from being transferred to the upper portion.

### 3-2. Flattening Step S2

As shown in FIG. 1, the flattening step S2 is performed after the initial nucleus forming step S1. The flattening step S2 according to the first embodiment is a step of growing a crystal by using an flux film coating (FFC) method, and is a step of repeatedly performing a process of: immersing the seed substrate 9 having the initial nuclei 3 formed thereon in the mixed melt 101 stored in the crucible 100; pulling up the seed substrate 9 from the mixed melt 101; and then heating the seed substrate 9 in a nitrogen atmosphere, to grow the GaN single crystal from the initial nuclei 3, to fill a space between the adjacent initial nuclei 3 with the GaN single crystal, and to flatten a crystal surface.

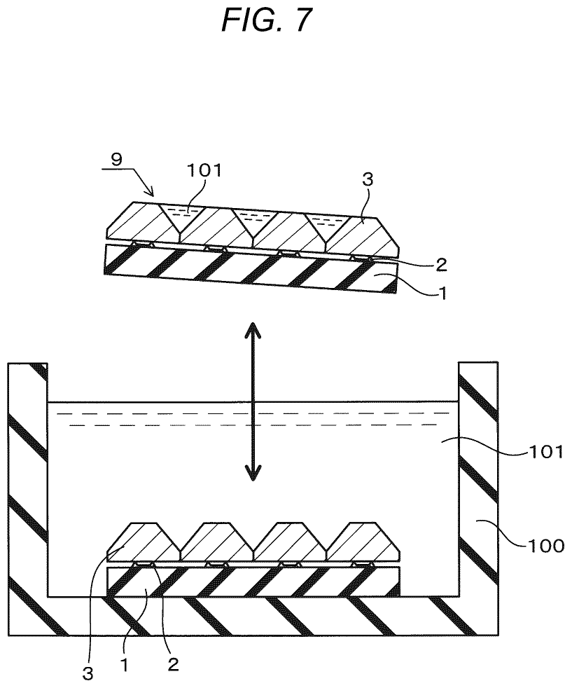

In the FFC method in the flattening step S2 according to the first embodiment, as shown in FIG. 7, the seed substrate 9 is repeatedly taken out of the mixed melt 101 and immersed in the mixed melt 101 at a predetermined cycle. In the case where the seed substrate 9 is taken out of the mixed melt 101, the seed substrate 9 is slightly inclined with respect to a horizontal plane. When adjacent initial nuclei 3 begin to combine with each other, a groove 4 is formed on the combined surface. When the seed substrate 9 is taken out of the mixed melt 101, the mixed melt 101 is in a state of accumulating in the groove 4 between the adjacent initial nuclei 3. Accordingly, a crystal 5 can be grown along the groove 4 (see (c) of FIG. 2).

Here, since the mixed melt 101 accumulated in the groove 4 is thin, nitrogen is likely to be supersaturated. Therefore, the crystal growth rate can be increased. On the other hand, since the amount of the accumulated mixed melt 101 is small, the amount of Ga is also small, and the crystal growth is not performed for a while. Therefore, the seed substrate 9 is immersed the mixed melt 101 and the seed substrate 9 is taken out of the mixed melt 101 again, whereby the mixed melt 101 containing Ga is intermittently supplied to the groove 4. The FFC method is performed until the groove 4 is filled by the growth of the crystal 5. Accordingly, a crystal having a flat c plane can be grown.

Although a duration of the flattening step S2 is not limited, in the first embodiment, the cycle of immersing and taking the seed substrate 9 in and out of the mixed melt 101 is to repeat, for 100 hours, one set including immersion for 1 minute, taking out, and then heating in a nitrogen atmosphere for 30 minutes, so as to fill the groove 4. Note that, in the flattening step S2, the immersion time in one set is not limited and can be appropriately set in a range of about 1 minute to 10 minutes, and the heating time in a nitrogen atmosphere is not limited and can be appropriately set in a range of about 10 minutes to 120 minutes.

### 3-3. Thickening Step S3

As shown in FIG. 1, the thickening step S3 is performed after the flattening step S2. The thickening step S3 is a step of repeatedly performing a process of: immersing a GaN substrate, which is the seed substrate 9 having the flattened crystal surface formed in the flattening step S2, in the Ga—Na mixed melt 101 stored in the crucible 100; pulling up the GaN substrate from the Ga—Na mixed melt 101; and then heating the GaN substrate in a nitrogen atmosphere, to form a thickened GaN single crystal 6 on the GaN substrate (seed substrate 9).

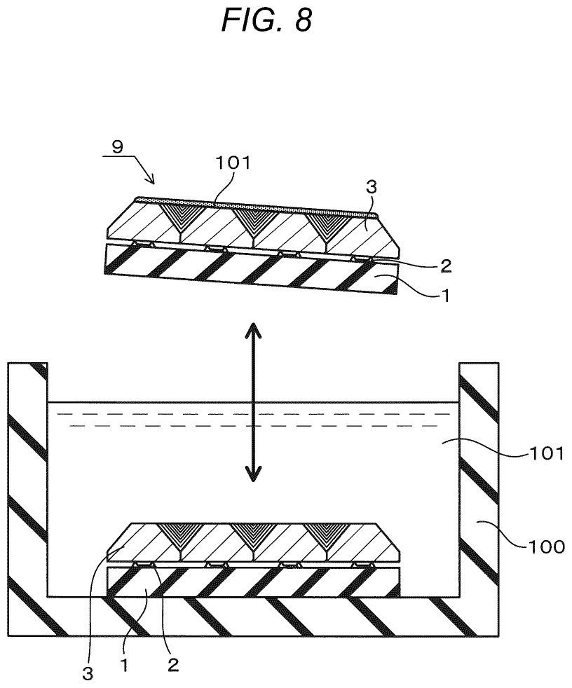

In the thickening step S3 according to the first embodiment, as shown in FIG. 8, the seed substrate 9 having a flat crystal surface is repeatedly immersed in the mixed melt 101 or taken out of the mixed melt 101 at a predetermined cycle. In the case where the seed substrate 9 is taken out of the mixed melt 101, the seed substrate 9 is slightly inclined with respect to the horizontal plane. Here, since the mixed melt 101 contains a trace amount of Ca as an impurity in the crucible 100 as described above, a trace amount of Ca melted from the crucible 100 is contained in the mixed melt 101 in the thickening step S3, and the content ratio of Ca in the thickening step S3 is less than 0.05 mol %. Note that, the content ratio of Ca melted from the crucible 100 in the mixed melt 101 increases as the time elapses after the mixed melt 101 is charged into the crucible 100. Therefore, when the initial nucleus forming step S1, the flattening step S2, and the thickening step S3 are compared, the content ratio of Ca melted from the crucible 100 in the mixed melt 101 is the smallest in the initial nucleus forming step S1 and increases in the order of the initial nucleus forming step S1, the flattening step S2, and the thickening step S3.

Wettability of the mixed melt 101 with respect to the crystal surface of the seed substrate 9 depends on the content ratio of the alkali metal other than Na or the alkaline earth metal in the mixed melt 101, and the wettability increases as the corresponding content ratio increases. Therefore, in the thickening step S3, the wettability of the mixed melt 101 with respect to the crystal surface of the seed substrate 9 is relatively high. Therefore, when the seed substrate 9 immersed in the mixed melt 101 is taken out of the mixed melt 101, a continuous thin layer of the mixed melt 101 is formed on the flat crystal surface of the seed substrate 9, as shown in FIG. 8.

On the other hand, in the thickening step S3, the content ratio of Ca in the mixed melt 101 is less than 0.05 mol %, and in the initial nucleus forming step S1 and the flattening step S2, the content ratio of Ca is further reduced. Accordingly, in each step, formation of a miscellaneous crystal other than the GaN single crystal 6 is prevented.

As shown in FIG. 8, since the thin layer of the mixed melt 101 formed on the flat crystal surface of the seed substrate 9 is thin, nitrogen is likely to be supersaturated as in the case of the flattening step S2. Therefore, the crystal growth rate can be increased. On the other hand, since the amount of the thin layer is small, the amount of Ga is also small, and crystal growth does not occur after a while. Therefore, the seed substrate 9 is immersed the mixed melt 101 and the seed substrate 9 is taken out of the mixed melt 101 again, whereby the mixed melt 101 containing Ga is intermittently supplied to the flat crystal surface. By repeating this, the GaN single crystal 6 is grown and thickened (see (d) of FIG. 2). Since the shapes of the respective initial nuclei 3 are uniform, the GaN single crystal 6 can also be formed uniformly in the plane. In addition, since the dislocation of the seed crystal 2 is prevented from being transferred to the upper portion, the GaN single crystal 6 can be formed with a high quality.

In the thickening step S3, the content ratio of Ca in the mixed melt 101 is less than 0.05 mol %; the immersion time, which is a time for immersing the GaN substrate (seed substrate 9) in the mixed melt 101, can be within a range of, for example, 1 minute to 10 minutes; a vapor phase heating time, which is a time for heating the GaN substrate (seed substrate 9) in a nitrogen atmosphere after being pulled up from the mixed melt 101, can be within a range of, for example, 10 minutes to 120 minutes; and the immersion of the GaN substrate (seed substrate 9) in the mixed melt 101 and the vapor phase heating can be repeated as one set for a predetermined time.

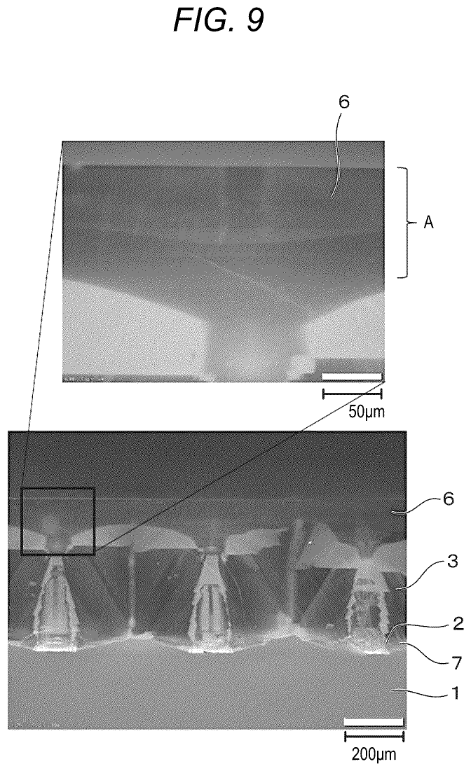

In the first embodiment, in the thickening step S3, the content ratio of Ca in the mixed melt 101 is 0.01 mol % to less than 0.05 mol %; the immersion time, which is the time for immersing the GaN substrate (seed substrate 9) in the mixed melt 101, is 1 minute; a vapor phase heating time, which is a time for heating the GaN substrate (seed substrate 9) in a nitrogen atmosphere after being pulled up from the mixed melt 101, is 30 minutes; and the immersion of the GaN substrate (seed substrate 9) in the mixed melt 101 and the vapor phase heating is repeated as one set for 50 hours. Accordingly, it is found that the GaN single crystal 6 having a thickness of about 100 μm can be formed by stacking a large number of layers of the GaN single crystal 6 having a thickness of about 1 μm in a region indicated by reference sign A in FIG. 9.

Note that, the duration of the thickening step S3 can be appropriately set according to a target thickness of the GaN single crystal 6. In addition, the immersion time and the heating time in a nitrogen atmosphere per one set in the thickening step S3 can also be appropriately set.

When the GaN single crystal 6 grows to a desired thickness, the temperature is lowered to room temperature, the pressure is also lowered to a normal pressure, and the growth of the GaN single crystal 6 is completed. Here, the gap between the initial nucleus 3 and the substrate 1 is not filled and remains. Therefore, the substrate 1 can be naturally peeled off when the temperature is lowered due to a difference in thermal expansion coefficient.

As described above, according to the GaN single crystal growth method in the first embodiment, the side surface 2a of the seed crystal 2 is the (10-11) plane. Therefore, the variation in shape of the respective initial nuclei 3 can be prevented, and a uniform and high quality GaN single crystal 6 can be formed.

In addition, the recess 2d is provided at the center of the seed crystal 2, and the seed crystal 2 has a shape in which the upper surface is not present. Therefore, the upper portion of the seed crystal 2 is not filled during the growth of the initial nuclei 3, and the void 7 is formed. As a result, the propagation of the dislocation of the seed crystal 2 to the upper portion can be prevented, and a high quality GaN single crystal 6 can be formed.

Note that, although the flattening step S2 based on the FFC method in the present embodiment is not necessarily performed, it is preferable to perform the flattening step S2 in order to further improve flatness of the crystal and further reduce the warpage.

### 3. Operations and Effects

Operations and effects of the Group III nitride single crystal growth method according to the first embodiment will be described below. With the Group III nitride single crystal growth method according to the first embodiment, since the mixed melt 101 containing Ga, which is a Group III metal, and Na is stored in the alumina crucible 100 containing an alkali metal other than Na or an alkaline earth metal, an extremely small amount of the alkali metal other than Na or the alkaline earth metal is melted into the mixed melt 101. Accordingly, the wettability of the mixed melt 101 with respect to the GaN substrate (seed substrate 9) can be improved, and formation of an inclusion is prevented. Further, since the amount of the alkali metal other than Na or the alkaline earth metal contained in the mixed melt 101 is extremely small, the formation of the miscellaneous crystal is also prevented. As a result, both the prevention of the formation of the inclusion and the prevention of the formation of the miscellaneous crystal are achieved, so that the crystal quality of the GaN single crystal 6 can be improved.

In addition, in the first embodiment, the alkali metal other than Na or the alkaline earth metal melted from the crucible 100 in the thickening step S3 is mixed in the mixed melt 101 at a ratio of 0.01 mol % to less than 0.05 mol %. Accordingly, since the ratio of the alkali metal other than Na or the alkaline earth metal contained in the mixed melt 101 in the thickening step S3 is extremely small, both the prevention of the formation of the inclusion and the prevention of the formation of the miscellaneous crystal can be further achieved.

In addition, in the first embodiment, in the thickening step S3, the immersion time, which is the time for immersing the GaN substrate (seed substrate 9) in the mixed melt 101, is in the range of 1 minute to 10 minutes, and the vapor phase heating time, which is the time for heating the GaN substrate (seed substrate 9) in a nitrogen atmosphere after being pulled up from the mixed melt 101, is in the range of 10 minutes to 120 minutes. The immersion time is relatively short, but is sufficient for supplying the mixed melt 101 to the upper surface of the GaN substrate, and the vapor phase heating time is sufficient for growing the GaN single crystal 6 using, as a raw material, the mixed melt 101 supplied to the upper surface of the GaN substrate. Therefore, in the thickening step S3, the growth of the GaN single crystal 6 can be efficiently performed while preventing the formation of the macrostep.

In addition, the first embodiment includes: the initial nucleus forming step S1 of immersing, in the mixed melt 101 stored in the crucible 100, the seed substrate 9 made of the GaN single crystal and having the plurality of seed crystals 2 formed on the upper surface thereof, to grow the GaN single crystal from the plurality of seed crystals 2 and to form the plurality of initial nuclei 3; and the flattening step S2 of repeatedly performing a process of: immersing the seed substrate 9 having the initial nuclei 3 formed thereon in the mixed melt 101 stored in the crucible 100; pulling up the seed substrate 9 from the mixed melt 101; and then heating the seed substrate 9 in a nitrogen atmosphere, to grow the GaN single crystal from the initial nuclei 3, to fill the space between the adjacent initial nuclei 3 with the GaN single crystal, and to flatten the crystal surface. Then, in the thickening step S3, the seed substrate 9 having the flattened crystal surface formed in the flattening step S2 is used as the GaN substrate. Accordingly, a thickened GaN single crystal 6 having a high crystal quality can be formed on the seed substrate 9.

In addition, in the first embodiment, the ratio of the alkali metal other than Na or the alkaline earth metal in the mixed melt 101 increases in the order of the initial nucleus forming step S1, the flattening step S2, and the thickening step S3. Accordingly, even when the wettability of the mixed melt 101 with respect to the seed substrate 9 is improved in the initial nucleus forming step S1, an influence on crystal formation is small, so that the formation of the miscellaneous crystal in the initial nucleus forming step S1 can be prevented by lowering the ratio of the alkali metal other than Na or the alkaline earth metal in the mixed melt 101. Further, by improving the wettability of the mixed melt 101 with respect to the GaN substrate (seed substrate 9) in the flattening step S2, the mixed melt 101 is likely to be held on the GaN substrate (seed substrate 9) when the GaN substrate (seed substrate 9) is pulled up from the mixed melt 101, so that the flattening of the crystal surface can be promoted. Further, in the thickening step S3, by further improving the wettability of the mixed melt 101, both the prevention of the formation of the inclusion and the prevention of the formation of the miscellaneous crystal can be further achieved.

As described above, according to the above embodiment and modification, it is possible to provide a Group III nitride single crystal growth method capable of improving the crystal quality.

The present invention is not limited to the above embodiment and modification, and may be applied to various embodiments without departing from the gist of the present invention.

### REFERENCE SIGNS LIST

1: substrate
2: seed crystal
2a: side surface
2b: bottom surface
2c: side surface
2d: recess
3: initial nucleus
4: groove
5, 6: crystal
9: seed substrate

What is claimed is:

1. A Group III nitride single crystal growth method, which is a method for growing a Group III nitride single crystal on a Group III nitride substrate, the method comprising:
a thickening step of repeatedly performing, to form a thickened Group III nitride single crystal on the Group III nitride substrate, a process of: immersing the Group III nitride substrate in a mixed melt containing a Group III metal and Na stored in a crucible; pulling up the Group III nitride substrate from the mixed melt; and heating the Group III nitride substrate, pulled up from the mixed melt, in a nitrogen atmosphere, wherein
the crucible is an alumina crucible containing alumina as a main component and containing an alkali metal other than Na or an alkaline earth metal.

2. The Group III nitride single crystal growth method according to claim 1, wherein the alkali metal other than Na or the alkaline earth metal melted from the crucible in the thickening step is mixed in the mixed melt at a ratio of 0.01 mol % to less than 0.05 mol %.

3. The Group III nitride single crystal growth method according to claim 1, wherein in the thickening step, an immersion time, which is a time for immersing the Group III nitride substrate in the mixed melt, is within a range of 1 minute to 10 minutes, and a vapor phase heating time, which is a time for heating the Group III nitride substrate in the nitrogen atmosphere after being pulled up from the mixed melt, is within a range of 10 minutes to 120 minutes.

4. The Group III nitride single crystal growth method according to claim 2, wherein in the thickening step, an immersion time, which is a time for immersing the Group III nitride substrate in the mixed melt, is within a range of 1 minute to 10 minutes, and a vapor phase heating time, which is a time for heating the Group III nitride substrate in the nitrogen atmosphere after being pulled up from the mixed melt, is within a range of 10 minutes to 120 minutes.

5. The Group III nitride single crystal growth method according to claim 1, further comprising:
an initial nucleus forming step of immersing, in the mixed melt stored in the crucible, a seed substrate having a plurality of seed crystals, made from a Group III nitride single crystal, formed on an upper surface of the seed substrate, to grow a Group III nitride single crystal from the plurality of seed crystals and to form a plurality of initial nuclei; and
a flattening step of repeatedly performing a process of: immersing the seed substrate having the initial nuclei formed thereon in the mixed melt stored in the crucible; pulling up the seed substrate from the mixed melt; and heating the seed substrate, pulled up from the mixed melt, in a nitrogen atmosphere, to grow a Group III nitride single crystal from the initial nuclei, to fill a space between the adjacent ones of the plurality of initial nuclei with the Group III nitride single crystal, so that a crystal surface of the seed substrate is flatten, wherein
in the thickening step, the seed substrate having the flattened crystal surface formed in the flattening step is used as the Group III nitride substrate.

6. The Group III nitride single crystal growth method according to claim 2, further comprising:
an initial nucleus forming step of immersing, in the mixed melt stored in the crucible, a seed substrate having a plurality of seed crystals, made from a Group III nitride single crystal, formed on an upper surface of the seed substrate, to grow a Group III nitride single crystal from the plurality of seed crystals and to form a plurality of initial nuclei; and
a flattening step of repeatedly performing a process of: immersing the seed substrate having the initial nuclei formed thereon in the mixed melt stored in the crucible; pulling up the seed substrate from the mixed melt; and heating the seed substrate, pulled up from the mixed melt, in a nitrogen atmosphere, to grow a Group III nitride single crystal from the initial nuclei, to fill a space between the adjacent ones of the plurality of initial nuclei with the Group III nitride single crystal, so that a crystal surface of the seed substrate is flatten, wherein
in the thickening step, the seed substrate having the flattened crystal surface formed in the flattening step is used as the Group III nitride substrate.

7. The Group III nitride single crystal growth method according to claim 5, wherein a ratio of the alkali metal other than Na or the alkaline earth metal in the mixed melt increases in an order of the initial nucleus forming step, the flattening step, and the thickening step.

8. The Group III nitride single crystal growth method according to claim 6, wherein a ratio of the alkali metal other than Na or the alkaline earth metal in the mixed melt increases in an order of the initial nucleus forming step, the flattening step, and the thickening step.
